(19) United States
(12) Patent Application Publication
(10) Pub. No.: US 2026/0271484 A1
(43) Pub. Date: Sep. 10, 2026

(54) SENSORS FOR DETECTING ULTRAVIOLET RAYS AND INFRARED RAYS

(71) Applicant: Samsung Electronics Co., Ltd., Suwon-si (KR)

(72) Inventors: Dae-Yong SON, Suwon-si (KR); Taehyung KIM, Suwon-si (KR); Kyung Bae PARK, Suwon-si (KR); Moon Gyu HAN, Suwon-si (KR)

(73) Assignee: Samsung Electronics Co., Ltd., Suwon-si (KR)

(21) Appl. No.: 19/452,619

(22) Filed: Jan. 19, 2026

(30) Foreign Application Priority Data
Mar. 7, 2025 (KR) 10-2025-0029764

(51) Int. Cl. H10K 39/32

(52) U.S. Cl. CPC H10K 39/32

(57) ABSTRACT

A sensor for detecting ultraviolet rays and infrared rays includes: a circuit board; a first electrode disposed on the circuit board; an electron transport layer disposed on the first electrode; an infrared ray photoelectric conversion layer disposed on the electron transport layer and including a quantum dot material for receiving light in an infrared ray region and generating photocharges; an ultraviolet ray photoelectric conversion layer disposed between the infrared ray photoelectric conversion layer and the hole transport layer; a hole transport layer disposed on the infrared ray photoelectric conversion layer; a second electrode disposed on the hole transport layer; and a visible light blocking filter disposed on the second electrode.

### CROSS-REFERENCE TO RELATED APPLICATION

This application claims priority to and the benefit of Korean Patent Application No. 10-2025-0029764 filed with the Korean Intellectual Property Office on Mar. 7, 2025, the entire contents of which are incorporated herein by reference.

### BACKGROUND

### (a) Field

The present inventive concepts relate to sensors for detecting ultraviolet rays and/or infrared rays.

### (b) Description of the Related Art

In modern society, sensors that detect ultraviolet rays and/or infrared rays are used in various fields such as water treatment, national defense, safety, flame detection, space communication, skin care, and health care. Ultraviolet rays may have a role in these fields, while the infrared rays are increasingly being utilized in night vision, tracking, remote temperature measurement, short-range wireless communication, spectroscopy, solar cells, biometric imaging, AR/VR, LIDAR, and ToF sensors.

Existing commercial photodetectors are mainly manufactured based on silicon (Si). However, since silicon shows a high reflection coefficient of about 6 in the ultraviolet ray region, photon absorption is not sufficient, so the entire photoconversion efficiency is limited to equal to or less than 20%. Increasing a gain to compensate for sensitivity requires increasing the intensity of ultraviolet rays, which may cause damage to the skin in applications such as skin care or health care.

### SUMMARY

Some example embodiments of the present inventive concepts provide sensors that alleviate volume and installation space problems in a system for sensing ultraviolet rays and infrared rays.

The present inventive concepts provide sensors that improve light absorption efficiency on a sensor for ultraviolet rays and infrared rays and improve detection sensitivity.

Sensors of some example embodiments of the present inventive concepts thereby provide solutions to problems with detection of infrared rays. For example, Si-based sensors show very low absorption efficiency in the IR region, particularly at wavelengths of equal to or greater than 1 μm, which limits their practical detection. Additionally, when using an IR sensor, there is a condition that specific wavelength bandwidths that water absorbs (equal to or less than 980 nm, equal to or less than 1150 nm, 1300 nm to 1500 nm, and 1780 nm to 2000 nm) must be avoided. For this reason, an alternative material whose absorption peak is controlled may be required to obtain accurate detection performance. When the ultraviolet rays and the infrared rays are to be detected, a current method for collecting data by separating the ultraviolet rays and the infrared rays using separate sensors is used. The method has the merit of using two sensors simultaneously, but the dual arrangement of sensors increases the volume of the entire system, increases installation space and design cost, and causes alignment problems and potential signal loss due to complicated optical design. The sensors according to some example embodiments of the present inventive concepts provide ultraviolet ray and infrared ray detection with reduced sensor volume and thus alleviate volume and installation space problems in a system for sensing ultraviolet rays and infrared rays, and such sensors may further and/or alternatively provide ultraviolet ray and infrared ray detection with improved light absorption efficiency and/or detection sensitivity and thus with reduced power consumption without compromising ultraviolet ray and/or infrared ray detection performance and/or efficiency of the sensors.

Some example embodiments of the present inventive concepts provide a sensor for detecting ultraviolet rays and infrared rays. The sensor may include: a circuit board; a first electrode on the circuit board; an electron transport layer on the first electrode; an infrared ray photoelectric conversion layer on the electron transport layer, the infrared ray photoelectric conversion layer including a quantum dot material, the quantum dot material configured to generate photocharges based on receiving the infrared rays, the infrared rays including light in an infrared ray region; a hole transport layer on the infrared ray photoelectric conversion layer; a second electrode on the hole transport layer; and a visible light blocking filter on the second electrode.

The sensor may further include an ultraviolet ray photoelectric conversion layer between the infrared ray photoelectric conversion layer and the hole transport layer. The ultraviolet ray photoelectric conversion layer may include a separate quantum dot material, the separate quantum dot material configured to generate separate photocharges based on receiving the ultraviolet rays, the ultraviolet rays including light in an ultraviolet ray region.

The quantum dot material included in the infrared ray photoelectric conversion layer may include at least one of silver telluride (Ag₂Te) or indium arsenic (InAs), and the separate quantum dot material included in the ultraviolet ray photoelectric conversion layer may include at least one of zinc oxide (ZnO), zinc selenide (ZnSe), zinc sulfide (ZnS), zinc telluride (ZnTe), barium tin oxide (BaSnO₃), or zinc tin oxide (Zn₂SnO₄).

The ultraviolet ray photoelectric conversion layer may include an inorganic film.

The sensor may further include a micro lens on the visible light blocking filter.

The sensor may be configured to detect the ultraviolet rays based on a first voltage being supplied between the first electrode and the second electrode, and detect the infrared rays based on a second voltage being supplied between the first electrode and the second electrode, the second voltage greater than the first voltage.

The first voltage may be 1V, and the second voltage may be equal to or greater than 3V.

The circuit board may be a readout integrated circuit (ROIC). The circuit board may include a transmission transistor TX, logic transistors RX, SX, and DX, a transmission gate TG, a floating diffusing region FD, and a control voltage supplying portion VC.

The sensor may further include an ultraviolet ray photoelectric conversion layer between the electron transport layer and the hole transport layer, the ultraviolet ray photoelectric conversion layer on a same layer as the infrared ray photoelectric conversion layer, such that the ultraviolet ray photoelectric conversion layer and the infrared ray photoelectric conversion layer at least partially overlap in a horizontal direction extending parallel to an upper surface of the same layer. The ultraviolet ray photoelectric conversion layer may include a separate quantum dot material. The separate quantum dot material may be configured to generate separate photocharges based on receiving the ultraviolet rays, the ultraviolet rays including light in an ultraviolet ray region.

The quantum dot material included in the infrared ray photoelectric conversion layer may include at least one of silver telluride (Ag₂Te) or indium arsenic (InAs). The separate quantum dot material included in the ultraviolet ray photoelectric conversion layer may include at least one of zinc oxide (ZnO), zinc selenide (ZnSe), zinc sulfide (ZnS), zinc telluride (ZnTe), barium tin oxide (BaSnO₃), or zinc tin oxide (Zn₂SnO₄). The ultraviolet ray photoelectric conversion layer may include an inorganic film.

The sensor may include a micro lens on the visible light blocking filter. The sensor may be configured to detect the ultraviolet rays based on a first voltage being supplied between the first electrode and the second electrode, and detect the infrared rays based on a second voltage being supplied between the first electrode and the second electrode, the second voltage greater than the first voltage. The first voltage may be 1V, and the second voltage may be equal to or greater than 3V.

Some example embodiments of the present inventive concepts provide a method for driving a sensor for detecting ultraviolet rays and infrared rays. The sensor may include a circuit board, a first electrode on the circuit board, an electron transport layer on the first electrode, an infrared ray photoelectric conversion layer on the electron transport layer, an ultraviolet ray photoelectric conversion layer on the electron transport layer, a hole transport layer on the infrared ray photoelectric conversion layer and the ultraviolet ray photoelectric conversion layer, a second electrode on the hole transport layer, and a visible light blocking filter on the second electrode. The infrared ray photoelectric conversion layer may be configured to generate photocharges based on receiving the infrared rays, the infrared rays including light in an infrared ray region, the ultraviolet ray photoelectric conversion layer configured to generate separate photocharges based on receiving the ultraviolet rays, the ultraviolet rays including light in an ultraviolet ray region. The method may include: detecting the ultraviolet rays based on supplying a first voltage between the first electrode and the second electrode; and detecting the infrared rays based on supplying a second voltage between the first electrode and the second electrode, the second voltage greater than the first voltage.

The first voltage may be 1V, and the second voltage may be equal to or greater than 3V.

The first electrode may include an infrared ray electrode and an ultraviolet ray electrode, the infrared ray electrode corresponding to the infrared ray photoelectric conversion layer, the ultraviolet ray electrode corresponding to the ultraviolet ray photoelectric conversion layer, the infrared ray electrode and the ultraviolet ray electrode separated from each other, and the detecting the ultraviolet rays may be based on supplying the first voltage between the ultraviolet ray electrode and the second electrode, the detecting the infrared rays may be based on supplying the second voltage between the infrared ray electrode and the second electrode, and the first voltage and the second voltage may be supplied simultaneously or sequentially.

According to some example embodiments, the sensor for detecting ultraviolet rays and infrared rays may be configured to detect the ultraviolet rays and the infrared rays with improved light absorption efficiency for selectively sensing ultraviolet rays and infrared rays according to the supplied voltage.

### BRIEF DESCRIPTION OF THE DRAWINGS

FIG. 1 shows a circuit diagram of a sensor for detecting ultraviolet rays and infrared rays according to some example embodiments.

FIG. 2 shows a cross-sectional view of a sensor for detecting ultraviolet rays and infrared rays according to some example embodiments.

FIG. 3 shows a cross-sectional view of a sensor for detecting ultraviolet rays and infrared rays according to some example embodiments.

FIG. 4 shows an external quantum efficiency (EQE) graph of a light blocking spectrum of a visible ray blocking filter applicable to some example embodiments and a sensor for detecting ultraviolet rays and infrared rays according to some example embodiments.

FIG. 5 shows a graph of a method for a sensor for detecting ultraviolet rays and infrared rays to respectively sense ultraviolet rays and infrared rays according to some example embodiments.

FIG. 6 shows a schematic view of a principle for a sensor for detecting ultraviolet rays and infrared rays to respectively sense ultraviolet rays and infrared rays according to some example embodiments.

FIG. 7 shows an energy band graph on example quantum dot materials applicable to a sensor for detecting ultraviolet rays and infrared rays according to some example embodiments.

FIG. 8 is a schematic view illustrating an example of an electronic device that includes a sensor for detecting ultraviolet rays and infrared rays according to some example embodiments.

### DETAILED DESCRIPTION

The present inventive concepts will be described more fully hereinafter with reference to the accompanying drawings, in which some example embodiments of the inventive concepts are shown. As those skilled in the art would realize, the described example embodiments may be modified in various different ways, all without departing from the spirit or scope of the present inventive concepts.

The drawings and the descriptions are to be considered as illustrative and not as restrictive. Throughout the specification, the same reference numbers indicate the same constituent elements.

Parts that are irrelevant to the description are omitted to clearly describe the present inventive concepts, and like reference numerals designate like elements throughout the specification. The thicknesses of layers, films, panels, regions, etc., are enlarged for clarity. The thicknesses of some layers and areas are exaggerated.

The singular forms are intended to include the plural forms as well, unless the context clearly indicates otherwise.

In the specification and the claims, the term “and/or” is intended to include arbitrary combinations of the terms “and” and “or” for the purposes of meaning and interpretation. For example, the expression of “A and/or B” may be understood to signify “A, B, or A and B”.

In the specification and claims, the phrase “at least one of” is intended to include the meaning of “at least one selected from the group of,” for the purpose of meaning and interpretation. For example, “at least one of A and B” may be understood to signify “A, B, or A and B”.

Terms such as first, second, and the like will be used only to describe various constituent elements, and are not to be interpreted as limiting these constituent elements. The terms are only used to differentiate one constituent element from other constituent elements. For example, a first constituent element could be termed a second constituent element, and similarly, a second constituent element could be termed as a first constituent element, without departing from the scope of the present inventive concepts.

When an element, such as a layer, a film, a region, or a substrate is described to be “above” another element, it may be directly above another element or there may be an intermediate element. In contrast, when a first element is described to be “directly above” a second element, there is no intermediate element. Throughout the specification, the term “above” a target must be “understood as being disposed above or below the target element, and does not necessarily signify “above” with respect to an opposite direction of gravity.

For example, spatially relative terms “below” or “above” may be used to facilitate the description of the relationship of one element or a constituent element to other constituent elements as shown in the drawings. The spatially relative terms are intended to include other directions in use or operation in addition to the directions shown in the drawings. For example, when the device shown in the drawing is flipped, the device disposed below another device may be disposed “above” the other device. Therefore, the example term “below” may include lower and upper positions. The device may also be oriented in other directions, the spatially relative term may be analyzed differently depending on the directions.

When an element (or region, layer, portion, etc.) is described to be “connected” or “combined” to another element in the specification, it may be directly disposed, connected, or combined on the above-noted other element, or an element may be disposed therebetween.

The term “connected to” or “combined to” may include physical or electrical connections or combinations.

Unless otherwise defined, all terms (including technical and scientific terms) used herein have the same meaning as commonly understood by one of ordinary skill in the art to which the present inventive concepts belong. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

It will be understood that elements and/or properties thereof (e.g., structures, surfaces, directions, or the like), which may be referred to as being “perpendicular,” “parallel,” or the like with regard to other elements and/or properties thereof (e.g., structures, surfaces, directions, or the like) may be “perpendicular,” “parallel,” or the like or may be “substantially perpendicular,” “substantially parallel,” or the like, respectively, with regard to the other elements and/or properties thereof.

Elements and/or properties thereof (e.g., structures, surfaces, directions, or the like) that are “substantially perpendicular” with regard to other elements and/or properties thereof will be understood to be “perpendicular” with regard to the other elements and/or properties thereof within manufacturing tolerances and/or material tolerances and/or have a deviation in magnitude and/or angle from “perpendicular,” or the like with regard to the other elements and/or properties thereof that is equal to or less than 10% (e.g., a tolerance of ±10%).

Elements and/or properties thereof (e.g., structures, surfaces, directions, or the like) that are “substantially parallel” with regard to other elements and/or properties thereof will be understood to be “parallel” with regard to the other elements and/or properties thereof within manufacturing tolerances and/or material tolerances and/or have a deviation in magnitude and/or angle from “parallel,” or the like with regard to the other elements and/or properties thereof that is equal to or less than 10% (e.g., a. tolerance of ±10%).

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

While the term “same,” “equal” or “identical” may be used in description of some example embodiments, it should be understood that some imprecisions may exist. Thus, when one element is referred to as being the same as another element, it should be understood that an element or a value is the same as another element within a desired manufacturing or operational tolerance range (e.g., ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the inventive concepts. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

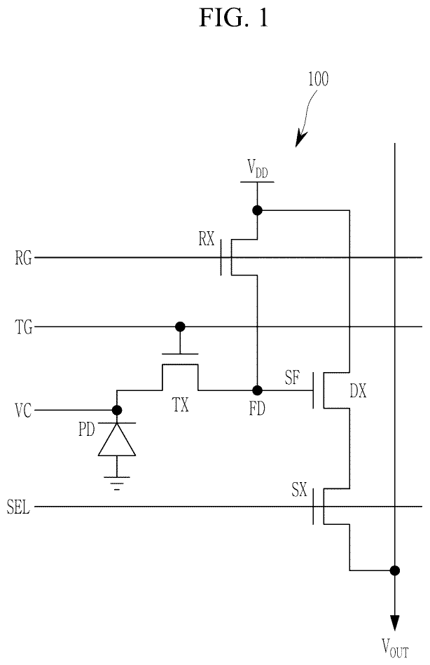

FIG. 1 shows a circuit diagram of a sensor 100 for detecting ultraviolet rays and infrared rays according to some example embodiments.

Referring to FIG. 1, a sensor 100 for detecting ultraviolet rays and infrared rays may include unit pixels, and the unit pixels may be arranged in a matrix format. The respective unit pixels may include a transmission transistor TX and logic transistors RX, SX, and DX. The logic transistors may be a reset transistor RX, a selection transistor SX, and a source follower transistor DX. The transmission transistor TX may include a transmission gate TG. The transmission gate TG may be a dual transmission gate which is a pair of two transmission gates. The respective unit pixels may further include a photoelectric converter PD and a floating diffusing region FD. A control voltage supplying portion VC may be connected to an end of the photoelectric converter PD. The logic transistors RX, SX, and DX may be shared by the unit pixels. The unit pixels may be divided into ultraviolet rays sensing pixels and infrared ray sensing pixels.

The photoelectric converter PD may generate and store photocharges in proportion to an incident amount (e.g., intensity) of external light (e.g., may generate and store photocharges based on receiving, for example absorbing, incident light, in proportion to an intensity of said incident light). The photoelectric converter PD may absorb ultraviolet rays and photoelectrically convert the same or may absorb infrared rays and photoelectrically convert the same according to a size of voltage supplied to the control voltage supplying portion VC. That is, the photoelectric converter PD may generate photocharges caused by ultraviolet rays or may generate photocharges caused by infrared rays by adjusting the voltage supplied to the control voltage supplying portion VC. For example, when 0V is supplied (applied) to the control voltage supplying portion VC, the photoelectric converter PD may generate no photocharges from (e.g., may not generate any photocharges based on receiving) the ultraviolet rays and the infrared rays; when 1V is supplied thereto, the photoelectric converter PD may generate photocharges caused by the ultraviolet rays (e.g., may generate photocharges based on receiving ultraviolet rays), and when 3V is supplied thereto, the photoelectric converter PD may generate photocharges caused by the ultraviolet rays and photocharges caused by the infrared rays (e.g., may generate photocharges based on receiving infrared rays). The amount of photocharges caused by infrared rays (e.g., generated based on the photoelectric converter PD receiving infrared rays) may be calculated by subtracting the amount of photocharges obtained (e.g., generated by the photoelectric converter PD) by supplying 1V from the amount of photocharges obtained (e.g., generated by the photoelectric converter PD) by supplying 3V. As a result, the sensor 100 may be configured to enable ultraviolet ray and infrared ray detection with reduced sensor volume and thus alleviate volume and installation space problems in a system for sensing ultraviolet rays and infrared rays. As another result, the sensor 100 may be configured to enable ultraviolet ray and infrared ray detection with improved light absorption efficiency and/or detection sensitivity. As another result, the sensor 100 may be configured to enable ultraviolet ray and infrared ray detection with reduced power consumption without compromising ultraviolet ray and/or infrared ray detection performance and/or efficiency of the sensor 100. Thus, the sensor 100 may exhibit improved ultraviolet ray detection and infrared ray detection functionality, miniaturization functionality, power consumption efficiency, any combination thereof, or the like.

The photoelectric converter PD may include a photodiode, a phototransistor, a photogate, a pinned photodiode, or any combinations thereof. The transmission transistor TX may transmit charges generated by the photoelectric converter PD to the floating diffusing region FD. The floating diffusing region FD may receive the charges from the photoelectric converter PD and may store them in an accumulative way. The source follower transistor DX may be controlled according to the amount of photocharges stored in the floating diffusing region FD.

The reset transistor RX may periodically reset the charges stored in the floating diffusing region FD. The reset transistor RX has a drain electrode connected to the floating diffusing region FD and a source electrode connected to a power source voltage (VDD). When the reset transistor RX is turned on, the power source voltage (VDD) connected to the source electrode of the reset transistor RX may be supplied to the floating diffusing region FD. Hence, when the reset transistor RX is turned on, the charges stored in the floating diffusing region FD may be discharged and the floating diffusing region FD may be reset.

The source follower transistor DX including a source follower gate electrode SF may function as a source follower buffer amplifier. The source follower transistor DX may amplify a potential change in the floating diffusing region FD, and may output it to the output line (Vout).

The selection transistor SX including a selection gate electrode SEL may select unit pixels to be read per row. When the selection transistor SX is turned on, the power source voltage (VDD) may be supplied to the drain electrode of the source follower transistor DX.

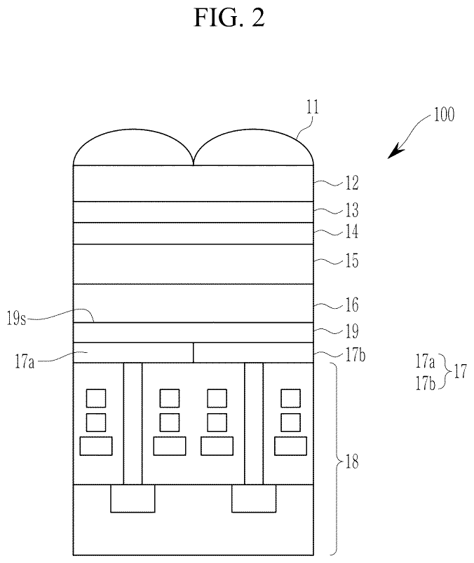

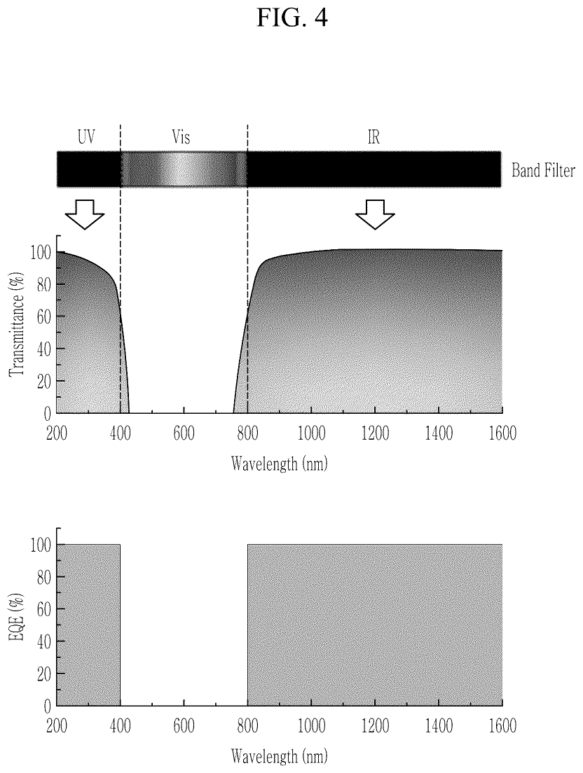

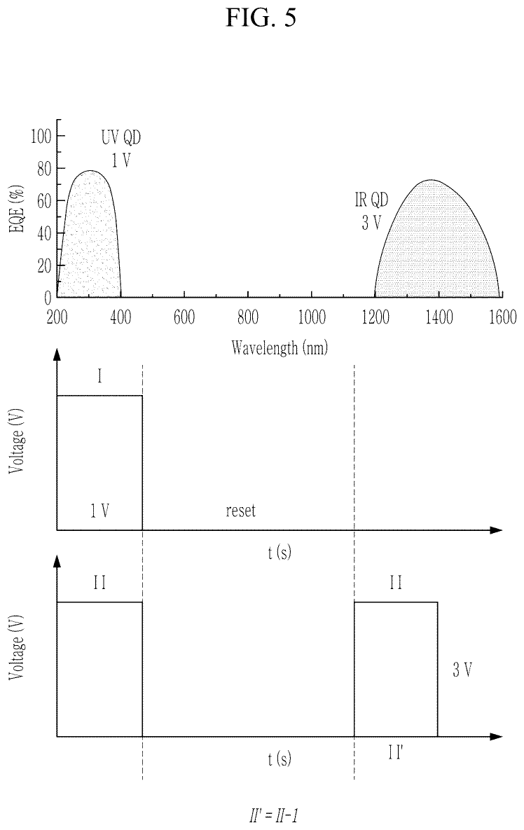

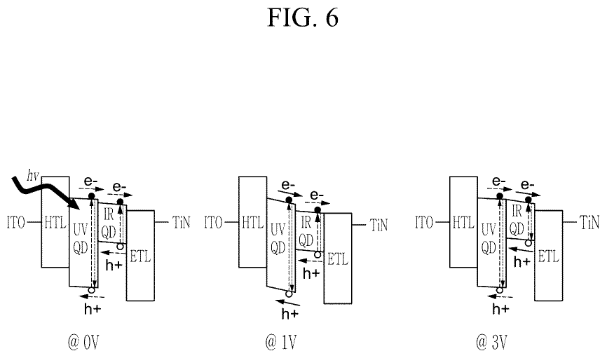

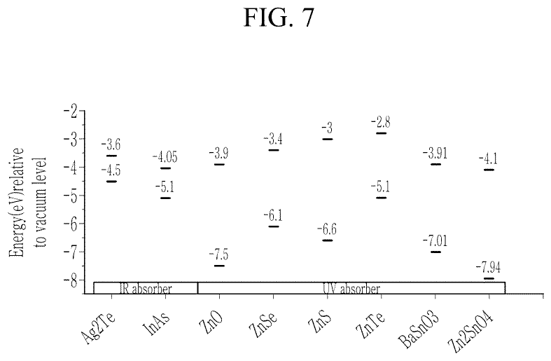

FIG. 2 shows a cross-sectional view of a sensor 100 for detecting ultraviolet rays and infrared rays according to some example embodiments. FIG. 4 shows an external quantum efficiency (EQE) graph of a light blocking spectrum of a visible ray blocking filter applicable to some example embodiments and a sensor 100 for detecting ultraviolet rays and infrared rays according to some example embodiments. FIG. 5 shows a graph of a method for a sensor 100 for detecting ultraviolet rays and infrared rays to respectively sense ultraviolet rays and infrared rays according to some example embodiments. FIG. 6 shows a schematic view of a principle for a sensor 100 for detecting ultraviolet rays and infrared rays to respectively sense ultraviolet rays and infrared rays according to some example embodiments. FIG. 7 shows an energy band graph of example quantum dot materials applicable to a sensor 100 for detecting ultraviolet rays and infrared rays according to some example embodiments. It will be understood that infrared rays may include light in an infrared ray region (e.g., an infrared wavelength spectrum, for example about a wavelength spectrum of about 800 nm to about 1600 nm). It will be understood that ultraviolet rays may include light in an ultraviolet ray region (e.g., an ultraviolet wavelength spectrum, for example about a wavelength spectrum of about 200 nm to about 400 nm).

Referring to FIG. 2, the sensor 100 for detecting ultraviolet rays and infrared rays may include: one or more first electrodes 17, an electron transport layer (ETL) 19, an infrared ray photoelectric conversion layer 16, an ultraviolet ray photoelectric conversion layer 15, a hole transport layer (HTL) 14, a second electrode 13, a visible light blocking filter 12, and a micro lens 11 sequentially disposed on a circuit board 18.

The circuit board 18 provides a basic foundation for physically supporting parts of the sensor 100 and electrically connecting them. The circuit board 18 may include various types of active devices and passive devices formed on a semiconductor substrate, and wiring layers and insulation layers for insulating the wiring layers formed on the semiconductor substrate, and it may be a readout integrated circuit (ROIC). The transmission transistor TX, the logic transistors RX, SX, and DX, the transmission gate TG, the floating diffusing region FD, and the control voltage supplying portion VC shown in the circuit diagram of FIG. 1 may be implemented on the circuit board 18.

The first electrode 17 may include one or more pixel electrodes, and may collect the charges generated by the photoelectric conversion layer(s) in an earlier stage. The first electrode 17 may be made of a metal thin membrane such as silver (Ag) or a transparent conductive material such as indium tin oxide (ITO). While the example embodiments shown in FIG. 2 illustrate multiple first electrodes 17 on the circuit board 18, example embodiments are not limited thereto.

The electron transport layer (ETL) 19 may be disposed on the first electrode(s) 17, may efficiently move electrons generated by the photoelectric conversion layer(s), and may block reverse movement of holes to separate electrons and holes, and thereby increase efficiency of extracting charges. The electron transport layer (ETL) 19 may include oxidized zinc (ZnO) and fullerene (C₆₀). In some example embodiments, the electron transport layer (ETL) 19 may be omitted.

The infrared ray photoelectric conversion layer 16 may be disposed near the electron transport layer (ETL) 19, may absorb light in the infrared ray region to generate pairs of electrons and holes and may convert them into electric signals, and thus may generate photocharges based on receiving (e.g., absorbing) light in the infrared ray region (e.g., infrared wavelength spectrum), such light also referred to herein as infrared rays. It will be understood that a layer “receiving” rays and/or light in a ray region, as described herein, may “absorb” such rays and/or light, photoelectrically convert such rays and/or light, or the like. The infrared ray photoelectric conversion layer 16 may include quantum dot (QD) materials which may include at least one of silver telluride (Ag₂Te), indium arsenic (InAs), etc., for absorbing light in the infrared ray region (wavelengths of about 800 nm to about 1600 nm) and generating pairs of electrons and holes. The energy band of the quantum dot (QD) materials is shown in FIG. 7.

The ultraviolet ray photoelectric conversion layer 15 may be disposed near the infrared ray photoelectric conversion layer 16, may absorb the light in the ultraviolet ray region (wavelengths of about 200 nm to about 400 nm) to generate pairs of electrons and holes, and may convert them into electric signals, and thus may generate photocharges (separate photocharges) based on receiving (e.g., absorbing) light in the ultraviolet ray region (e.g., ultraviolet wavelength spectrum), such light also referred to herein as ultraviolet rays. The ultraviolet ray photoelectric conversion layer 15 may include quantum dot (QD) materials (e.g., separate quantum dot materials), which may include at least one of oxidation zinc (ZnO), zinc selenide (ZnSe), zinc sulfide (ZnS), zinc telluride (ZnTe), barium tin oxide (BaSnO₃), or zinc tin oxide (Zn₂SnO₄), for absorbing the light in the ultraviolet ray region and generating pairs of electrons and holes. The energy band of the quantum dot (QD) materials is shown in FIG. 7.

The ultraviolet photoelectric conversion layer (15) among the infrared photoelectric conversion layer (16) and the ultraviolet photoelectric conversion layer (15) described above may be omitted. For example, when indium arsenic (InAs) is used as the infrared ray photoelectric conversion layer 16, and no additional ultraviolet ray photoelectric conversion layer 15 is provided, the infrared rays may be detected and the ultraviolet rays may be detected using the infrared ray photoelectric conversion layer 16. For example, the infrared ray photoelectric conversion layer 16 may be configured to generate photocharges based on receiving (e.g., absorbing) light in an infrared ray region (e.g., infrared rays), for example based on a first voltage being applied to the sensor, and may be configured to generate photocharges (e.g., separate photocharges) based on receiving (e.g., absorbing) light in an ultraviolet ray region (e.g., ultraviolet rays), for example based on a second voltage that is the same as or different from the first voltage being applied to the sensor. As a result, the sensor 100 may be configured to enable ultraviolet ray and infrared ray detection with reduced sensor volume and thus alleviate volume and installation space problems in a system for sensing ultraviolet rays and infrared rays. As another result, the sensor 100 may be configured to enable ultraviolet ray and infrared ray detection with improved light absorption efficiency and/or detection sensitivity. As another result, the sensor 100 may be configured to enable ultraviolet ray and infrared ray detection with reduced power consumption without compromising ultraviolet ray and/or infrared ray detection performance and/or efficiency of the sensor 100. Thus, the sensor 100 may exhibit improved ultraviolet ray detection and infrared ray detection functionality, miniaturization functionality, power consumption efficiency, any combination thereof, or the like.

In some example embodiments, one of the infrared ray photoelectric conversion layer 16 or the ultraviolet ray photoelectric conversion layer 15 may include quantum dot materials, and the other may be an inorganic film such as Perovskite. In s ome example embodiments, at least one of the infrared ray photoelectric conversion layer 16 or the ultraviolet ray photoelectric conversion layer 15 may include both of one or more quantum dot materials and an inorganic film such as Perovskite.

The hole transport layer (HTL) 14 may be disposed on the ultraviolet ray photoelectric conversion layer 15, and may efficiently move the generated holes, may maintain separation from electrons, and may increase the entire charge collecting efficiency. The second electrode 13 may be adjacent to the hole transport layer (HTL) 14, and may collect the transported charges, and may transmit the same to an external circuit. The hole transport layer (HTL) 14 may include PEDOT: PSS(Poly (3,4-ethylenedioxythiophene): poly(styrene sulfonate)). The hole transport layer (HTL) 14 may be omitted.

The visible light blocking filter 12 may block the visible rays reaching from an outside of the sensor 100 to allow the ultraviolet rays and the infrared rays to be input to the sensor. As shown in FIG. 4, the visible light blocking filter 12 may absorb or reflect the light in the wavelength region of about 400 nm to about 800 nm (e.g., visible light) to block such light in the wavelength region of about 400 nm to about 800 nm, and may allow the light in other wavelength regions (e.g., infrared rays, ultraviolet rays, etc.) to pass through the visible light blocking filter 12 (e.g., to the infrared photoelectric conversion layer 16 and/or the ultraviolet photoelectric conversion layer 15). A multilayered dielectric thin membrane filter manufactured by alternatively depositing dielectric materials with different refractive indexes such as a film of titanium oxide (TiO) or a film of silicon oxide (SiO) may be used for the visible light blocking filter 12. In some example embodiments, the visible light blocking filter 12 may be omitted.

The micro lens 11 may collect light provided from the outside and may focus it on the photoelectric conversion layer, thereby increasing sensitivity and efficiency of the sensor. In some example embodiments, the micro lens 11 may be omitted.

When a particular (or, alternatively, predetermined) first voltage, for example 1V, is supplied (e.g., applied) between the first electrode 17 and the second electrode 13 of the sensor 100 for detecting ultraviolet rays and infrared rays (such supplying of voltage being referred to as applying said voltage to the sensor 100 and/or to one or more photoelectric conversion layers thereof that are between the first electrode 17 and the second electrode 13), an ultraviolet ray absorbing quantum dot material or a photoelectric conversion film of the ultraviolet ray photoelectric conversion layer 15 is activated and photocharges are generated by the ultraviolet rays (portion I of FIG. 5), and when a particular (or, alternatively, predetermined) second voltage, for example 3V, is supplied, an infrared ray absorbing quantum dot or a photoelectric conversion film of the infrared ray photoelectric conversion layer 16 is activated in addition to the ultraviolet ray absorbing quantum dot material (e.g., separate quantum dot material) or the photoelectric conversion film of the ultraviolet ray photoelectric conversion layer 15, photocharges are generated by the ultraviolet rays and the infrared rays and may be stored (portion II of FIG. 5). The photocharges (II′=II−I) caused by infrared rays may be obtained (e.g., determined, detected, etc.) by subtracting the photocharges (I) caused by ultraviolet rays from the above-obtained photocharges (II). As a result, the sensor 100 may be configured to enable ultraviolet ray and infrared ray detection with reduced sensor volume and thus alleviate volume and installation space problems in a system for sensing ultraviolet rays and infrared rays. As another result, the sensor 100 may be configured to enable ultraviolet ray and infrared ray detection with improved light absorption efficiency and/or detection sensitivity. As another result, the sensor 100 may be configured to enable ultraviolet ray and infrared ray detection with reduced power consumption without compromising ultraviolet ray and/or infrared ray detection performance and/or efficiency of the sensor 100. Thus, the sensor 100 may exhibit improved ultraviolet ray detection and infrared ray detection functionality, miniaturization functionality, power consumption efficiency, any combination thereof, or the like.

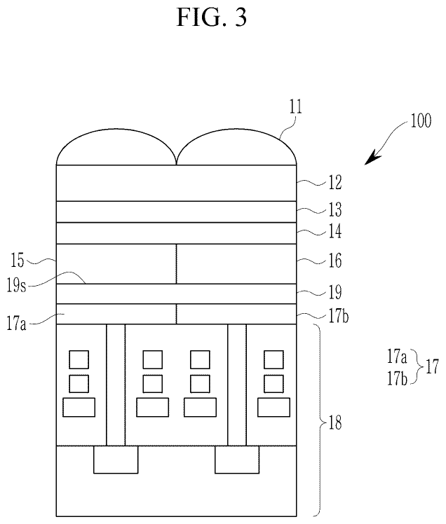

FIG. 6 shows an operational principle of an ultraviolet ray photoelectric conversion layer 15 and an infrared ray photoelectric conversion layer 16 of a sensor 100 for detecting ultraviolet rays and infrared rays (e.g., the sensor 100 shown in FIG. 2 and/or FIG. 3).

FIG. 3 shows a cross-sectional view of a sensor 100 for detecting ultraviolet rays and infrared rays according to some example embodiments.

Referring to FIG. 3, the sensor 100 for detecting ultraviolet rays and infrared rays may include first electrodes 17, an electron transport layer (ETL) 19, an infrared ray photoelectric conversion layer 16, an ultraviolet ray photoelectric conversion layer 15, a hole transport layer (HTL) 14, a second electrode 13, a visible light blocking filter 12, and a micro lens 11 sequentially disposed on the circuit board 18. Compared to some example embodiments, including the example embodiments shown in FIG. 2, some example embodiments, including the example embodiments shown in FIG. 3 have a different arrangement of the ultraviolet photoelectric conversion layer (15) and the infrared photoelectric conversion layer (16). In some example embodiments, including the example embodiments shown in FIG. 3, the ultraviolet ray photoelectric conversion layer 15 and the infrared ray photoelectric conversion layer 16 are arranged to occupy different regions on the same layer, and the first electrodes 17 are arranged to respectively correspond to the ultraviolet ray photoelectric conversion layer 15 and the infrared ray photoelectric conversion layer 16. For example, as shown, the first electrodes 17 may include a (1-1)-th first electrode 17a respectively corresponding to (e.g., overlapped in a thickness direction perpendicular to surface 19s by) the ultraviolet photoelectric conversion layer 15 and a (1-2)-th first electrode 17b respectively corresponding to (e.g., overlapped in the thickness direction by) the infrared photoelectric conversion layer 16. For example, as shown in FIG. 3, the ultraviolet ray photoelectric conversion layer 15 may be on (e.g., directly or indirectly on) a same layer as the infrared ray photoelectric conversion layer 16 (e.g., the electron transport layer (ELT) 19), such that the ultraviolet ray photoelectric conversion layer 16 and the infrared ray photoelectric conversion layer 15 at least partially overlap in a horizontal direction extending parallel to an upper surface of the same layer (e.g., the upper surface 19s of the electron transport layer (ELT) 19), for example such that the ultraviolet ray photoelectric conversion layer 16 and the infrared ray photoelectric conversion layer 15 are on (e.g., directly or indirectly on) and overlap separate portions of the same layer (e.g., separate portions of the electron transport layer (ELT) 19) in a thickness direction of the same layer (e.g., a direction perpendicular to the upper surface 19s) and thus may overlap separate, (1-1)-th and (1-2)-th first electrodes 17a and 17b of the first electrode 17 in the thickness direction. Hence, the sensor 100 according to some example embodiments, including the example embodiments shown in FIG. 3, may be configured to detect (also referred to herein as “sense”) ultraviolet rays and infrared rays simultaneously or sequentially detected based on supplying different voltages to the (1-1)-th first electrode 17a (or an ultraviolet ray electrode) corresponding to (e.g., overlapped in the thickness direction by) the ultraviolet ray photoelectric conversion layer 15 and the (1-2)-th first electrode 17 (or an infrared ray electrode) corresponding to (e.g., overlapped in the thickness direction by) the infrared ray photoelectric conversion layer 16. For example, the sensor 100 according to some example embodiments may be configured to detect ultraviolet rays based on a first voltage being supplied between a first electrode 17 (e.g., a (1-1)-th first electrode 17a overlapped by the ultraviolet ray photoelectric conversion layer 15 in a thickness direction perpendicular to upper surface 19s) and the second electrode 13, and detect infrared rays based on a second voltage being supplied between a first electrode 17 (e.g., a (1-2)-th first electrode 17b overlapped by the infrared ray photoelectric conversion layer 16 in the thickness direction perpendicular to upper surface 19s) and the second electrode 13, the second voltage greater than the first voltage. As a result, the sensor 100 may be configured to enable ultraviolet ray and infrared ray detection with reduced sensor volume and thus alleviate volume and installation space problems in a system for sensing ultraviolet rays and infrared rays. As another result, the sensor 100 may be configured to enable ultraviolet ray and infrared ray detection with improved light absorption efficiency and/or detection sensitivity. As another result, the sensor 100 may be configured to enable ultraviolet ray and infrared ray detection with reduced power consumption without compromising ultraviolet ray and/or infrared ray detection performance and/or efficiency of the sensor 100. Thus, the sensor 100 may exhibit improved ultraviolet ray detection and infrared ray detection functionality, miniaturization functionality, power consumption efficiency, any combination thereof, or the like.

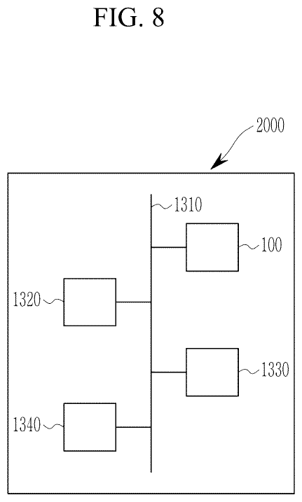

FIG. 8 is a schematic view illustrating an example of an electronic device that includes a sensor 100 for detecting ultraviolet rays and infrared rays according to some example embodiments.

Referring to FIG. 8, the electronic device 2000 includes a sensor 100, a bus 1310, a processor 1320, a memory 1330, and at least one additional device 1340. The sensor 100 may include any sensor 100 configured to detect ultraviolet rays and infrared rays according to any of the example embodiments. Information of the aforementioned sensor 100, processor 1320, memory 1330, and at least one additional device 1340 may be transferred to each other through the bus 1310.

The processor 1320 may include processing circuitry such as a hardware including logic circuits; a hardware/software combination such as processor-implemented software; or any combination thereof. For example, the processing circuitry may be a central processing unit (CPU), an arithmetic logic unit (ALU), a digital signal processor, a microcomputer, a field programmable gate array (FPGA), System-on-Chip (SoC), a programmable logic unit, a microprocessor, an application-specific integrated circuit (ASIC), or the like. As an example, the processing circuitry may include a non-transitory computer readable storage device. The processor 1320 (e.g., a central processing unit or CPU) may, for example, control an operation of the sensor 100, for example based on executing an instruction program stored at the memory 1330 (e.g., a solid-state drive (SSD) storage device).

The memory 1330 may store an instruction program, and the processor 1320 may perform a function related to the sensor 100 based on executing the instruction program.

The at least one additional device 1340 may be one or more communication interfaces (e.g., wireless communication interfaces, wired interfaces), user interfaces (e.g., keyboard, mouse, buttons, etc.), power supply and/or power supply interfaces, or any combination thereof.

The units and/or modules described herein may be implemented using hardware constituent elements and software constituent elements. For example, the hardware constituent elements may include microphones, amplifiers, band pass filters, audio-to-digital converters, and processing devices. The processing device may be implemented using one or more hardware devices configured to perform and/or execute program code by performing arithmetic, logic, and input/output operations. The processing device may include a processor, a controller and an arithmetic logic unit, a digital signal processor, a microcomputer, a field programmable array, a programmable logic unit, a microprocessor, or any other device capable of responding to and executing instructions. The processing device may access, store, operate, process, and generate data in response to execution of an operating system (OS) and one or more software running on the operating system.

The software may include a computer program, a code, an instruction, or any combination thereof, and may transform a processing device for a special purpose by instructing and/or configuring the processing device independently or collectively to operate as desired. The software and data may be implemented permanently or temporarily as signal waves capable of providing or interpreting instructions or data to machines, parts, physical or virtual equipment, computer storage media or devices, or processing devices. The software may also be distributed over networked computer systems so that the software may be stored and executed in a distributed manner. The software and data may be stored by one or more non-transitory computer readable storage devices.

In some example embodiments, the electronic device 2000 may be configured to cause different voltages to be supplied between first and second electrodes of the sensor 100 (e.g., based on the processor 1320 executing a program of instruction stored at the memory 1330 to control a supply of electrical power from a power supply (e.g., in the at least one additional device 1340) to the sensor 100 so as to cause an infrared ray photoelectric conversion layer 16 and/or an ultraviolet ray photoelectric conversion layer 16 of the sensor 100 to generate photocharges based on receiving (e.g., absorbing) light in the infrared ray region and/or the ultraviolet ray region. The electronic device 2000 may be configured to cause different voltages to be supplied to the sensor 100, to be applied between first and second electrodes thereof simultaneously or sequentially, to enable simultaneously or sequentially detecting infrared rays and/or ultraviolet rays.

For example, in example embodiments where the sensor 100 includes a sensor according to example embodiments shown in FIG. 2, wherein the infrared ray photoelectric conversion layer 15 and the ultraviolet ray photoelectric conversion layer 16 are stacked on the circuit board 18, the electronic device 2000 may be configured to (e.g., based on the processor 1320 executing a program of instructions stored at the memory 1330) control electrical power supplied from a power supply to initially supply a first voltage to the sensor 100 (and thus between the first and second electrodes 13 and 17 thereof) to cause the infrared ray photoelectric conversion layer 15 of the sensor 100 to generate photocharges based on receiving (e.g., absorbing) incident infrared rays (e.g., light in the infrared ray region) and to subsequently supply a second, different voltage to the sensor 100 (and thus between the first and second electrodes 13 and 17 thereof) to cause at least one of the infrared ray photoelectric conversion layer 15 or an ultraviolet ray photoelectric conversion layer 16 of the sensor 100 to generate separate photocharges based on receiving (e.g., absorbing) incident ultraviolet rays (e.g., light in the ultraviolet ray region). It will be understood that a photoelectric conversion layer of the sensor 100 generating photocharges may be referred to interchangeably as the sensor 100 generating the photocharges. The processor 1320 may detect infrared rays based on receiving and processing the photocharges generated by the sensor 100 in response to the supplying of the first voltage. The processor 1320 may detect ultraviolet rays based on receiving and processing the separate photocharges generated by the sensor 100 in response to the supplying of the second voltage, including for example based on determining a difference between the amount of the separate photocharges generated in response to the supplying of the second voltage from the amount of the photocharges generated by the sensor 100 in response to the supplying of the first voltage. Accordingly, the electronic device 2000 may be configured to sequentially detect infrared rays and ultraviolet rays using a same sensor 100.

In another example, in example embodiments where the sensor 100 includes a sensor according to example embodiments shown in FIG. 3, wherein the infrared ray photoelectric conversion layer 15 and the ultraviolet ray photoelectric conversion layer 16 are on separate portions of a same layer (e.g., at least partially overlapping in a horizontal direction and overlap separate portions of the same layer), the electronic device 2000 may be configured to (e.g., based on the processor 1320 executing a program of instructions stored at the memory 1330) control electrical power supplied from a power supply to supply a first voltage between the second electrode 13 and a particular first electrode 17 (e.g., (1-2)-th first electrode 17b) of the sensor 100 which overlaps/is overlapped by the infrared photoelectric conversion layer 16 in the thickness direction of the sensor 100 (e.g., a direction perpendicular to upper surface 19s) to cause the infrared ray photoelectric conversion layer 15 of the sensor 100 to generate photocharges based on receiving (e.g., absorbing) incident infrared rays (e.g., light in the infrared ray region) and to simultaneously or subsequently supply a second, different voltage between the second electrode 13 and a separate first electrode 17 (e.g., (1-1)-th first electrode 17a) of the sensor 100 which overlaps/is overlapped by the ultraviolet photoelectric conversion layer 15 in the thickness direction of the sensor 100 (e.g., a direction perpendicular to upper surface 19s) to cause the ultraviolet ray photoelectric conversion layer 16 of the sensor 100 to generate separate photocharges based on receiving (e.g., absorbing) incident ultraviolet rays (e.g., light in the ultraviolet ray region). It will be understood that a photoelectric conversion layer of the sensor 100 generating photocharges may be referred to interchangeably as the sensor 100 generating the photocharges. The processor 1320 may detect infrared rays based on receiving and processing the photocharges generated by the sensor 100 (e.g., between the second electrode 13 and the particular first electrode 17 overlapping/overlapped by the infrared ray photoelectric conversion layer 15) in response to the supplying of the first voltage. The processor 1320 may detect ultraviolet rays based on receiving and processing the separate photocharges generated by the sensor 100 (e.g., between the second electrode 17 and the separate first electrode 17 overlapping/overlapped by the ultraviolet ray photoelectric conversion layer 16) in response to the supplying of the second voltage. Such detection of the infrared rays and the ultraviolet rays may be performed simultaneously or sequentially, for example based on simultaneously supplying the first and second voltages between separate pairs of the second electrode and separate first electrodes 17 and detecting photocharges generated by the respective photoelectric conversion layers 15/16 therebetween and/or based on sequentially supplying the first and second voltages between separate pairs of first/second electrodes.

As a result of electronic device 2000 being configured to control the sensor 100 to detect ultraviolet rays and infrared rays simultaneously or sequentially based on supplying different voltages to the sensor 100 and processing signals received from the sensor 100 (including detecting rays based on determining a difference between signals received as a result of supplying different voltages to the sensor 100), the electronic device 2000 may be configured to enable ultraviolet ray and infrared ray detection using the sensor 100 with reduced sensor volume and thus enable improved miniaturization of the electronic device 2000. As another result of such configured control, the electronic device 2000 may be configured to enable ultraviolet ray and infrared ray detection with improved light absorption efficiency and/or detection sensitivity based on using the sensor 100. As another result of such configured control, the electronic device 2000 may be configured to enable ultraviolet ray and infrared ray detection with reduced power consumption without compromising ultraviolet ray and/or infrared ray detection performance and/or efficiency of the sensor 100. Thus, the electronic device 2000 may exhibit improved ultraviolet ray detection and infrared ray detection functionality, miniaturization functionality, power consumption efficiency, any combination thereof, or the like.

While the inventive concepts have been described in connection with what is presently considered to be practical embodiments, it is to be understood that the inventive concepts are not limited to such example embodiments, but, on the contrary, are intended to cover various modifications and equivalent arrangements included within the spirit and scope of the appended claims.

<Description of symbols>

| | |
|---|---|
| photoelectric converter PD, | floating diffusing region FD |
| transmission transistor TX, | reset transistor RX |
| selection transistor SX, | source follower transistor DX |
| control voltage VC, | transmission gate TG |
| micro lens 11, | visible light blocking filter 12 |
| second electrode 13, | hole transport layer (HTL) 14 |
| ultraviolet ray photoelectric | infrared ray photoelectric |
| conversion layer 15, | conversion layer 16 |
| electron transport layer (ETL) 19, | first electrode 17 |
| circuit board 18 | |

What is claimed is:

1. A sensor for detecting ultraviolet rays and infrared rays, the sensor comprising:
a circuit board;
a first electrode on the circuit board;
an electron transport layer on the first electrode;
an infrared ray photoelectric conversion layer on the electron transport layer, the infrared ray photoelectric conversion layer including a quantum dot material, the quantum dot material configured to generate photocharges based on receiving the infrared rays, the infrared rays including light in an infrared ray region;
a hole transport layer on the infrared ray photoelectric conversion layer;
a second electrode on the hole transport layer; and
a visible light blocking filter on the second electrode.

2. The sensor of claim 1, further comprising:
an ultraviolet ray photoelectric conversion layer between the infrared ray photoelectric conversion layer and the hole transport layer.

3. The sensor of claim 2, wherein:
the ultraviolet ray photoelectric conversion layer includes a separate quantum dot material, the separate quantum dot material configured to generate separate photocharges based on receiving the ultraviolet rays, the ultraviolet rays including light in an ultraviolet ray region.

4. The sensor of claim 3, wherein:
the quantum dot material included in the infrared ray photoelectric conversion layer includes at least one of silver telluride (Ag₂Te) or indium arsenic (InAs), and
the separate quantum dot material included in the ultraviolet ray photoelectric conversion layer includes at least one of zinc oxide (ZnO), zinc selenide (ZnSe), zinc sulfide (ZnS), zinc telluride (ZnTe), barium tin oxide (BaSnO₃), or zinc tin oxide (Zn₂SnO₄).

5. The sensor of claim 2, wherein:
the ultraviolet ray photoelectric conversion layer includes an inorganic film.

6. The sensor of claim 1, further comprising:
a micro lens on the visible light blocking filter.

7. The sensor of claim 6, wherein the sensor is configured to:
detect the ultraviolet rays based on a first voltage being supplied between the first electrode and the second electrode, and
detect the infrared rays based on a second voltage being supplied between the first electrode and the second electrode, the second voltage greater than the first voltage.

8. The sensor of claim 7, wherein:
the first voltage is 1V, and
the second voltage is equal to or greater than 3V.

9. The sensor of claim 8, wherein:
the circuit board is a readout integrated circuit (ROIC).

10. The sensor of claim 9, wherein:
the circuit board includes a transmission transistor TX, logic transistors RX, SX, and DX, a transmission gate TG, a floating diffusing region FD, and a control voltage supplying portion VC.

11. The sensor of claim 1, further comprising:
an ultraviolet ray photoelectric conversion layer between the electron transport layer and the hole transport layer, the ultraviolet ray photoelectric conversion layer on a same layer as the infrared ray photoelectric conversion layer, such that the ultraviolet ray photoelectric conversion layer and the infrared ray photoelectric conversion layer at least partially overlap in a horizontal direction extending parallel to an upper surface of the same layer.

12. The sensor of claim 11, wherein:
the ultraviolet ray photoelectric conversion layer includes a separate quantum dot material, the separate quantum dot material configured to generate separate photocharges based on receiving the ultraviolet rays, the ultraviolet rays including light in an ultraviolet ray region.

13. The sensor of claim 12, wherein:
the quantum dot material included in the infrared ray photoelectric conversion layer includes at least one of silver telluride (Ag₂Te) or indium arsenic (InAs), and
the separate quantum dot material included in the ultraviolet ray photoelectric conversion layer includes at least one of zinc oxide (ZnO), zinc selenide (ZnSe), zinc sulfide (ZnS), zinc telluride (ZnTe), barium tin oxide (BaSnO₃), or zinc tin oxide (Zn₂SnO₄).

14. The sensor of claim 11, wherein:
the ultraviolet ray photoelectric conversion layer includes an inorganic film.

15. The sensor of claim 11, further comprising:
a micro lens on the visible light blocking filter.

16. The sensor of claim 15, wherein the sensor is configured to:
detect the ultraviolet rays based on a first voltage being supplied between the first electrode and the second electrode, and
detect the infrared rays based on a second voltage being supplied between the first electrode and the second electrode, the second voltage greater than the first voltage.

17. The sensor of claim 16, wherein:
the first voltage is 1V, and
the second voltage is equal to or greater than 3V.

18. A method for driving a sensor for detecting ultraviolet rays and infrared rays, the sensor including a circuit board, a first electrode on the circuit board, an electron transport layer on the first electrode, an infrared ray photoelectric conversion layer on the electron transport layer, an ultraviolet ray photoelectric conversion layer on the electron transport layer, a hole transport layer on the infrared ray photoelectric conversion layer and the ultraviolet ray photoelectric conversion layer, a second electrode on the hole transport layer, and a visible light blocking filter on the second electrode, the infrared ray photoelectric conversion layer configured to generate photocharges based on receiving the infrared rays, the infrared rays including light in an infrared ray region, the ultraviolet ray photoelectric conversion layer configured to generate separate photocharges based on receiving the ultraviolet rays, the ultraviolet rays including light in an ultraviolet ray region, the method comprising:
detecting the ultraviolet rays based on supplying a first voltage between the first electrode and the second electrode; and
detecting the infrared rays based on supplying a second voltage between the first electrode and the second electrode, the second voltage greater than the first voltage.

19. The method of claim 18, wherein:
the first voltage is 1V, and
the second voltage is equal to or greater than 3V.

20. The method of claim 18, wherein:
the first electrode includes an infrared ray electrode and an ultraviolet ray electrode, the infrared ray electrode corresponding to the infrared ray photoelectric conversion layer, the ultraviolet ray electrode corresponding to the ultraviolet ray photoelectric conversion layer, the infrared ray electrode and the ultraviolet ray electrode separated from each other, and
the detecting of the ultraviolet rays is based on supplying the first voltage between the ultraviolet ray electrode and the second electrode, the detecting of the infrared rays is based on supplying the second voltage between the infrared ray electrode and the second electrode, and the first voltage and the second voltage are supplied simultaneously or sequentially.
